(19) United States
(12) Patent Application Publication
(10) Pub. No.: US 2024/0022227 A1
(43) Pub. Date: Jan. 18, 2024

(54) ACOUSTIC RESONATOR AND FILTER DEVICE WITH BALANCED CHIRPING

(71) Applicant: Murata Manufacturing Co., Ltd., Nagaokakyo-shi (JP)

(72) Inventors: John P. KOULAKIS, Los Angeles, CA (US); Greg DYER, Santa Barbara, CA (US)

(21) Appl. No.: 18/353,979

(22) Filed: Jul. 18, 2023

Related U.S. Application Data
(60) Provisional application No. 63/390,121, filed on Jul. 18, 2022.

(51) Int. Cl. H03H 9/02; H03H 3/013

(52) U.S. Cl. CPC H03H 9/02228; H03H 9/02015; H03H 3/013; H03H 9/02086

(57) ABSTRACT

An acoustic resonator is provided that includes a substrate; a piezoelectric layer supported by the substrate; and an interdigital transducer (IDT) at a surface of the piezoelectric layer. The IDT includes a pair of busbars and a plurality of electrode fingers extending from the first and second busbars to be interleaved with each other. The respective widths of at least a portion of the electrode fingers increases in a direction from respective first ends of the first and second busbars to the respective second end of the first and second busbars. Moreover, a pitch of the portion of the electrode fingers decreases in the direction from the respective first ends of the first and second busbar to the respective second ends of the first and second busbars.

### CROSS REFERENCE TO RELATED APPLICATIONS

This application claims priority to U.S. Patent Provisional Application No. 63/390,121, filed Jul. 18, 2022, the entire contents of which are hereby incorporated by reference.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band may depend on the specific application. For example, in some cases a “pass-band” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

### SUMMARY

As described herein, chirping is a technique for acoustic resonators used to spread out the impact of spurs on a filter response and improve the overall filter to operate at different frequency bands. In particular, the varying of the pitch of the IDT fingers and the varying of the width or “mark” of the fingers along the length of the IDT may be generally referred to as “chirping”, which is used to spread out the impact of spurs on the resonance response. Accordingly, the exemplary aspects implement both mark and pitch chirping in a way in which the frequency shift of the main mode cancels. Moreover, the spur sensitivity to the mark and pitch changes is different than for the main mode, and their frequency shift does not cancel. As a result, this configuration chirps spurs while avoiding increased loss near resonance.

Thus, according to an exemplary embodiment an acoustic resonator is provided that includes a substrate; a piezoelectric layer supported by the substrate; and an interdigital transducer (IDT) at a surface of the piezoelectric layer. In this aspect, the IDT includes a first busbar and a second busbar that each extend in a first direction from a first end to a second end thereof, a first plurality of electrode fingers extending from the first busbar in a second direction towards the second busbar, with the second direction intersecting the first direction, and a second plurality of electrode fingers extending from the second busbar in the second direction towards to the first busbar, such that the first and second plurality of electrode fingers are interleaved with each other. According to the exemplary aspect, one of a pitch or respective widths of at least a portion of the interleaved electrode fingers of the first and second plurality of electrode fingers is chirped to spread out a spur impact of a frequency response in a primary mode of the acoustic resonator, and the other of the pitch and the widths of the portion of the interleaved electrode fingers is chirped to at least partially cancel a change of the frequency response in the primary mode.

In another exemplary aspect of the acoustic resonator, the other of the pitch and the widths of the portion of the interleaved electrode fingers is chirped to cancel at least 50% of the change of the frequency response.

In another exemplary aspect of the acoustic resonator, the respective widths of the portion of the electrode fingers of the first and second plurality of electrode fingers increases in a direction from the respective first ends of the first and second busbars to the respective second end of the first and second busbars, and the pitch of the portion of the electrode fingers decreases in the direction from the respective first ends of the first and second busbar to the respective second ends of the first and second busbars.

In another exemplary aspect of the acoustic resonator, the portion of the electrode fingers comprises a plurality of sections of interleaved fingers with increasing widths for each section of the plurality of sections, and the respective widths of interleaved fingers in each section is constant

In another exemplary aspect of the acoustic resonator, the respective widths of the electrode fingers of the first and second pluralities of electrode fingers are measured relative to the first direction.

In another exemplary aspect of the acoustic resonator, the substrate includes a base and an intermediate layer and a portion of the piezoelectric layer forms a diaphragm that spans a cavity that extends at least partially in the intermediate layer. In this aspect, the IDT is disposed on a surface of the piezoelectric layer that faces the cavity. Moreover, the piezoelectric layer and the IDT can be configured such that radio frequency signals applied to the IDT excites a primary shear acoustic mode in the diaphragm.

In another exemplary aspect of the acoustic resonator, the first direction is substantially perpendicular to the second direction.

In another exemplary aspect, the acoustic resonator further comprises a Bragg mirror disposed between the piezoelectric layer and the substrate.

In another exemplary aspect, a filter device is provided that includes a substrate; at least one piezoelectric layer supported by the substrate; and a plurality of interdigital transducers (IDTs) at a surface of the at least one piezoelectric layer. In this aspect, each IDT includes a first busbar and a second busbar that each extend in a first direction from a first end to a second end thereof, a first plurality of electrode fingers extending from the first busbar in a second direction towards the second busbar, with the second direction intersecting the first direction, and a second plurality of electrode fingers extending from the second busbar in the second direction towards to the first busbar, such that the first and second plurality of electrode fingers are interleaved with each other. In this aspect, a first IDT of the plurality of IDTs comprises a first ratio of mark chirp to pitch chirp of the electrode fingers of the first and second pluralities of the electrode fingers of the first IDT, and a second IDT of the plurality of IDTs comprises a second ratio of mark chirp to pitch chirp of the electrode fingers of the first and second pluralities of the electrode fingers of the second IDT, with the second ratio being different than the first ratio.

In another exemplary aspect of the filter device, for the first IDT, respective widths of the electrode fingers of the first plurality of electrode fingers increases at a first rate in the direction from the first end of the first busbar to the second end of the first busbar, and, for the second IDT, respective widths of the electrode fingers of the first plurality of electrode fingers increases at a second rate in the direction from the first end of the first busbar to the second end of the first busbar, the second rate being different than the first rate.

In another exemplary aspect of the filter device, a pitch of the interleaved fingers of the first IDT decreases in the direction from the first end of the first busbar of the first IDT to the second end of the first busbar of the first IDT, and a pitch of the interleaved fingers of the second IDT decreases in the direction from the first end of the first busbar of the second IDT to the second end of the first busbar of the second IDT.

In another exemplary aspect of the filter device, the respective widths of the electrode fingers of the first and second pluralities of electrode fingers of each of the plurality of IDTs are measured relative to the first direction.

In another exemplary aspect of the filter device, the first and second busbars of each of the plurality of IDTs extend in the first direction and are parallel to each other and the second direction is substantially perpendicular to the first direction.

In another exemplary aspect of the filter device, the substrate includes a base and an intermediate layer and respective portions of the at least one piezoelectric layer form a plurality of diaphragms that span a plurality of cavities that extend at least partially in the intermediate layer.

In another exemplary aspect of the filter device, the plurality of IDTs is disposed on a surface of the at least one piezoelectric layer that faces the plurality of cavities.

In another exemplary aspect of the filter device, the at least one piezoelectric layer and the plurality of IDTs are each configured such that radio frequency signals applied to each IDT excites a primary shear acoustic mode in the respective diaphragm.

In another exemplary aspect, the filter device further includes a Bragg mirror disposed between the at least one piezoelectric layer and the substrate.

In another exemplary aspect of the filter device, one of the mark chirp and the pitch chirp of the first IDT spreads out a spur impact of a frequency response in a primary mode of a first acoustic resonator that includes the first IDT, and the other of the mark chirp and the pitch chirp of the first IDT at least partially cancel a change of the frequency response in the primary mode of the first acoustic resonator.

In another exemplary aspect of the filter device, one of the mark chirp and the pitch chirp of the second IDT spreads out a spur impact of a frequency response in a primary mode of a second acoustic resonator that includes the first IDT, and the other of the mark chirp and the pitch chirp of the second IDT at least partially cancel a change of the frequency response in the primary mode of the second acoustic resonator.

The above simplified summary of example aspects serves to provide a basic understanding of the present disclosure. This summary is not an extensive overview of all contemplated aspects, and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1 includes a schematic plan view and two schematic cross-sectional views of a transversely-excited film bulk acoustic resonator (XBAR).

FIG. 2A is an expanded schematic cross-sectional view of a portion of the XBAR of FIG. 1.

FIG. 2B is an expanded schematic cross-sectional view of an alternative configuration of the XBAR of FIG. 1.

FIG. 2C is an expanded schematic cross-sectional view of another alternative configuration of the XBAR of FIG. 1.

FIG. 2D is an expanded schematic cross-sectional view of another alternative configuration of the XBAR of FIG. 1.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5 is a schematic block diagram of a filter using XBARs of FIG. 1.

FIG. 6 is an expanded cross-sectional view of an IDT configuration with balanced chirping of an XBAR of according to an exemplary aspect.

FIG. 7 illustrates a graph with pitch only chirping according to an exemplary aspect.

FIG. 8 illustrates a graph with mark only chirping according to an exemplary aspect.

FIG. 9 illustrates a graph with a balanced chirping according to an exemplary aspect.

FIG. 10 illustrates a flowchart of a method of manufacturing a filter device as described herein according to an exemplary aspect.

### DETAILED DESCRIPTION

Various aspects of the disclosed acoustic resonator, filter device and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

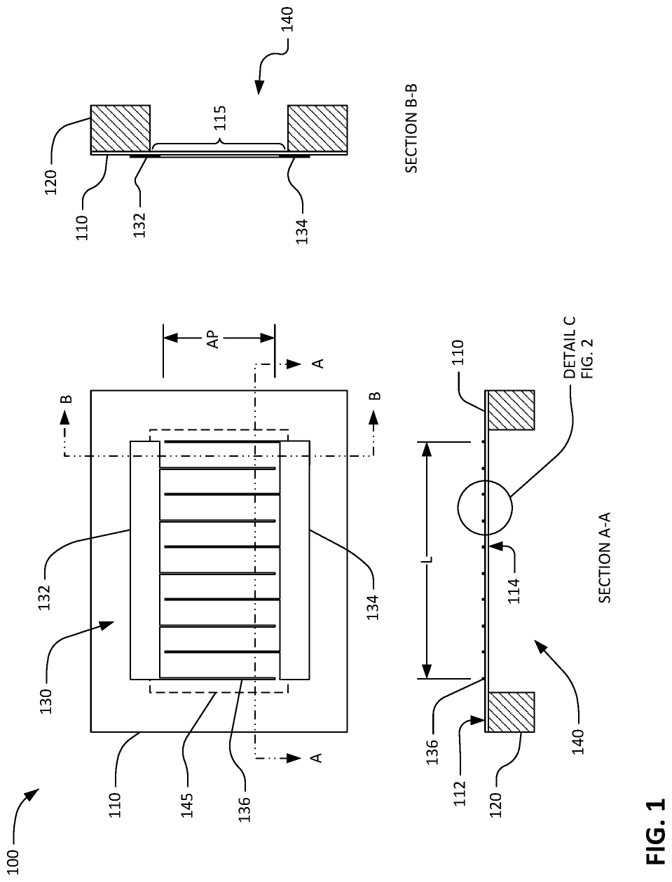

FIG. 1 shows a simplified schematic top view and orthogonal cross-sectional views of a transversely-excited film bulk acoustic resonator (XBAR) 100. XBAR resonators, such as the resonator 100, may be used in a variety of RF filters including band-reject filters, band-pass filters, duplexers, and multiplexers. XBARs are particularly suited for use in filters for communications bands with frequencies above 3 GHz.

In general, the XBAR 100 is made up of a thin film conductor pattern formed at one or both surfaces of a piezoelectric layer 110 (herein piezoelectric plate or piezoelectric layer may be used interchangeably) having parallel front and back surfaces 112, 114, respectively (also referred to generally first and second surfaces, respectively). According to an exemplary aspect, the piezoelectric layer is a thin single-crystal layer of a piezoelectric material, such as lithium niobate, lithium tantalate, lanthanum gallium silicate, gallium nitride, or aluminum nitride. The piezoelectric layer is cut such that the orientation of the X, Y, and Z crystalline axes with respect to the front and back surfaces is known and consistent. In the examples described herein, the piezoelectric layers are Z-cut, which is to say the Z axis is normal to the front and back surfaces 112, 114. However, XBARs may be fabricated on piezoelectric layers with other crystallographic orientations including rotated Z-cut and rotated YX cut.

The back surface 114 of the piezoelectric layer 110 may be at least partially supported by a surface of the substrate 120 except for a portion of the piezoelectric layer 110 that forms a diaphragm 115 spanning a cavity 140 formed one or more layers in the substrate. The phrase “supported by” may, as used herein, mean attached directly, attached indirectly, or any combination thereof. The portion of the piezoelectric layer that spans (e.g., extends over) the cavity is referred to herein as the “diaphragm” 115 due to its physical resemblance to the diaphragm of a microphone. As shown in FIG. 1, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

Moreover, the substrate 120 is configured to provide mechanical support to the piezoelectric layer 110. The substrate 120 may be, for example, silicon, sapphire, quartz, or some other material or combination of materials. The back surface 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

For purposes of this disclosure, “cavity” has its conventional meaning of “an empty space within a solid body.” The cavity 140 may be a hole completely through the substrate 120 (as shown in Section A-A and Section B-B) or a recess in the substrate 120. The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other. The interleaved fingers overlap for a distance AP, commonly referred to as the “aperture” of the IDT. The center-to-center distance L between the outermost fingers of the IDT 130 is the “length” of the IDT.

In the example of FIG. 1, the IDT 130 is on the front surface 112 (e.g., the first surface) of the piezoelectric layer 110. However, as discussed below, in other configurations, the IDT 130 may be on the back surface 114 (e.g., the second surface) of the piezoelectric layer 110 or on both the front and back surfaces 112, 114 of the piezoelectric layer 110.

The first and second busbars 132, 134 are configured as the terminals of the XBAR 100. In operation, a radio frequency or microwave signal applied between the two busbars 132, 134 of the IDT 130 excites a primary acoustic mode within the piezoelectric layer 110. As will be discussed in further detail, the primary acoustic mode is a bulk shear mode where acoustic energy of a bulk shear acoustic wave propagates along a direction substantially orthogonal to the surface of the piezoelectric layer 110, which is also normal, or transverse, to the direction of the electric field created by the IDT fingers. For purposes of this disclosure, “primary acoustic mode’ may generally refer to an operational mode in which a vibration displacement is caused in the thickness-shear direction, so the wave propagates substantially in the direction connecting the opposing front and back surfaces of the piezoelectric layer, that is, in the Z direction. In other words, the X-direction component of the wave is significantly smaller than the Z-direction component. The use of the term “primary” in the “primary acoustic mode” is not necessarily referring to a lower or higher order mode. Thus, the XBAR is considered a transversely-excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate. The exemplary aspects described below provide for improved thermal transport to improve performance (e.g., Q-factor) of the resonator.

In an event, the IDT 130 is positioned at or on the piezoelectric layer 110 such that at least the fingers of the IDT extend at or on the diaphragm 115 of the piezoelectric layer that spans, or is suspended over, the cavity 140. As shown in FIG. 1, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

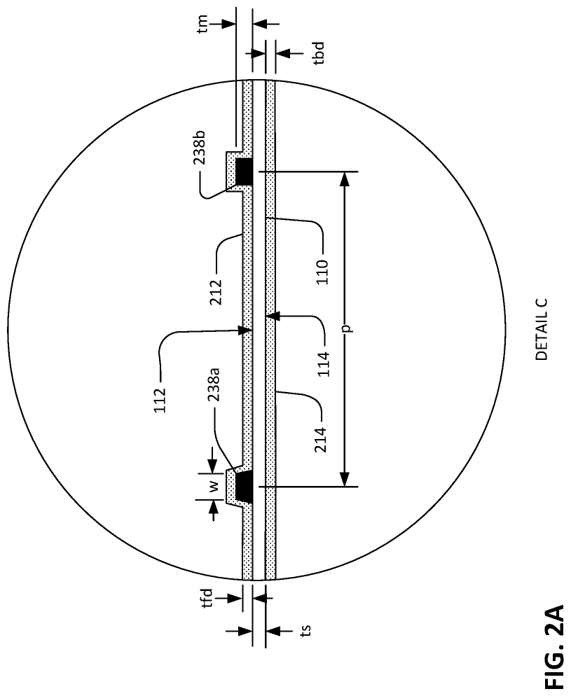

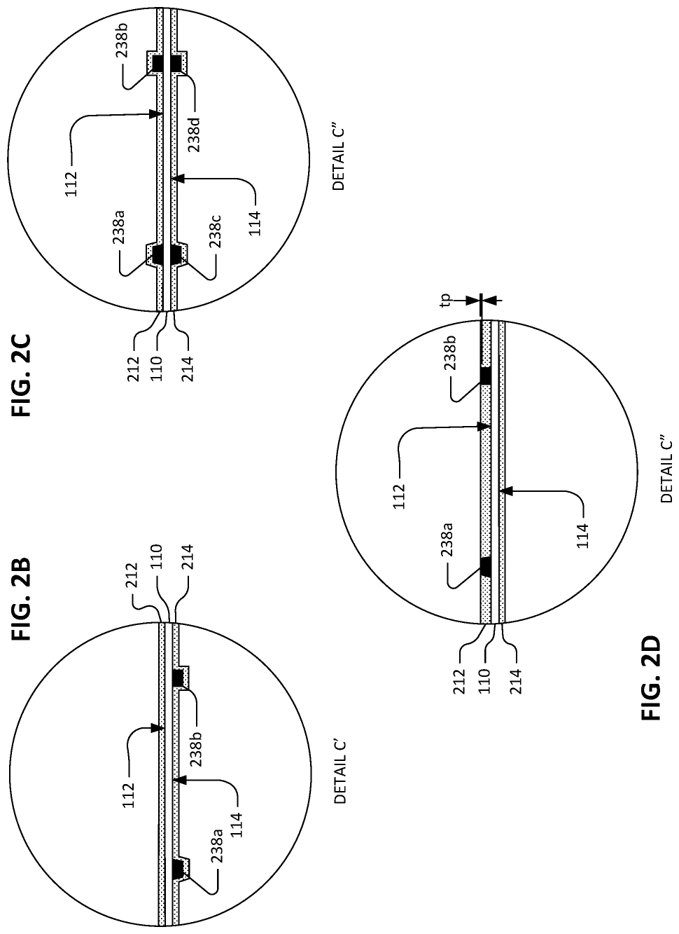

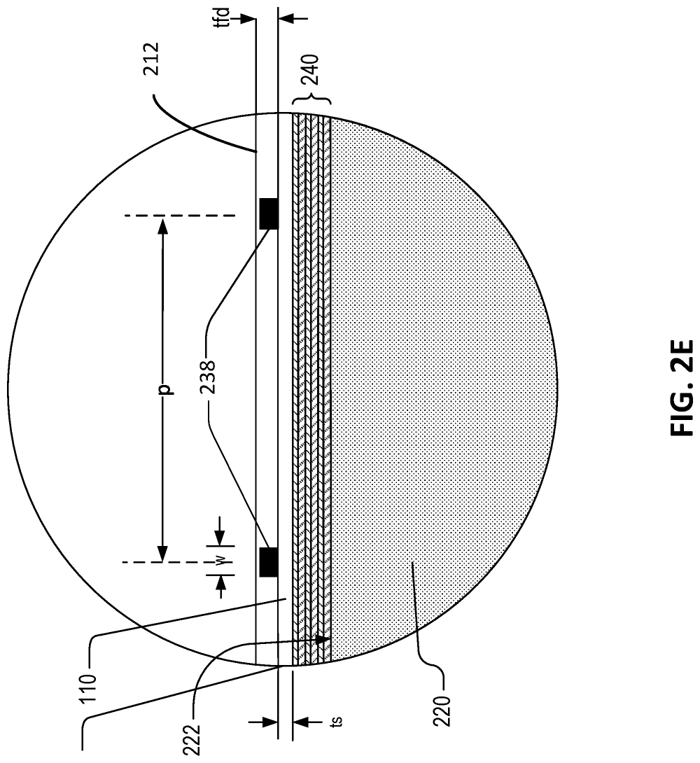

FIG. 2A shows a detailed schematic cross-sectional view of the XBAR 100 of FIG. 1. The piezoelectric layer 110 is a single-crystal layer of piezoelectrical material having a thickness ts. ts may be, for example, 100 nm to 1500 nm. When used in filters for 5G NR and Wi-Fi™ bands from 3.4 GHZ to 7 GHz, the thickness ts may be, for example, 150 nm to 500 nm.

In this aspect, a front-side dielectric layer 212 (e.g., a first dielectric coating layer or material) can be formed on the front side 112 of the piezoelectric layer 110. The “front side” of the XBAR is, by definition, the surface facing away from the substrate. The front-side dielectric layer 212 has a thickness tfd. As shown in FIG. 2A the front-side dielectric layer 212 covers the IDT fingers 238a, 238b, which can correspond to fingers 136 as described above with respect to FIG. 1. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back-side dielectric layer 214 (e.g., a second dielectric coating layer or material) can also be formed on the back side 114 of the piezoelectric layer 110. In general, for purposes of this disclosure, the term “back-side” means on a side opposite the conductor pattern of the IDT structure and/or opposite the front-side dielectric layer 212. Moreover, the back-side dielectric layer 214 has a thickness tbd. The front-side and back-side dielectric layers 212, 214 may be a non-piezoelectric dielectric material, such as silicon dioxide or silicon nitride. tfd and tbd may be, for example, 0 to 500 nm. tfd and tbd may be less than the thickness ts of the piezoelectric layer. tfd and tbd are not necessarily equal, and the front-side and back-side dielectric layers 212, 214 are not necessarily the same material. Either or both of the front-side and back-side dielectric layers 212, 214 may be formed of multiple layers of two or more materials according to various exemplary aspects.

The IDT fingers 238a, 238b may be aluminum, substantially aluminum alloys, copper, substantially copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1) of the IDT may be made of the same or different materials as the fingers. The cross-sectional shape of the IDT fingers may be trapezoidal (finger 238a), rectangular (finger 238b) or some other shape in various exemplary aspects.

Dimension p is the center-to-center spacing between adjacent IDT fingers, such as the IDT fingers 238a, 238b in FIGS. 2A-2C. Generally, the center-to-center spacing may be constant over the length of the IDT, in which case the dimension p may be referred to as the pitch of the IDT and/or the pitch of the XBAR. However, according to an exemplary aspect as will be discussed in more detail below, the center-to-center spacing varies along the length of the IDT, in which case the pitch of the IDT is the average value of dimension p over the length of the IDT. Each IDT finger, such as the IDT fingers 238a, 238b in FIGS. 2A, 2B, and 2C, has a width w measured normal to the long direction of each finger. The width w may also be referred to herein as the “mark.” In general, the width of the IDT fingers may be constant over the length of the IDT, in which case the dimension w is the width of each IDT finger. However, in an exemplary aspect as will be discussed below, the width of individual IDT fingers varies along the length of the IDT 130, in which case dimension w is the average value of the widths of the IDT fingers over the length of the IDT. Note that the pitch p and the width w of the IDT fingers are measured in a direction parallel to the length L of the IDT, as defined in FIG. 1.

The varying of the pitch of the IDT fingers and the varying of the width or “mark” of the fingers along the length of the IDT is generally referred to as “chirping”, which is used to spread out the impact of spurs on the resonance response. That is, chirping is the variation of the mark, pitch or both over the resonator length, and spreads in frequency both spurs and the main resonance. The spreading of the main resonance is an undesirable effect which increases loss near resonance. Moreover, spurs that are good candidates for chirping are those which move over a much larger frequency range than the main resonance. As will be described in detail below, the exemplary aspects implement both mark and pitch chirping in a way in which the frequency shift of the main mode cancels. Moreover, the spur sensitivity to the mark and pitch changes is different than for the main mode, and their frequency shift does not cancel. As a result, this configuration chirps spurs while avoiding increased loss near resonance. It should be appreciated that chirping as used in the configurations described herein effectively spreads out spurs, i.e., decreases their admittance or intensity at the spur frequency and creates a spur peak admittance that is wider and flatter. In some cases, a spur that falls in the passband cannot be moved out, but the balanced chirping described herein makes the spur less sharp and the spurious admittance response more muted, without spreading out the primary mode since the chirping will be balanced as described herein.

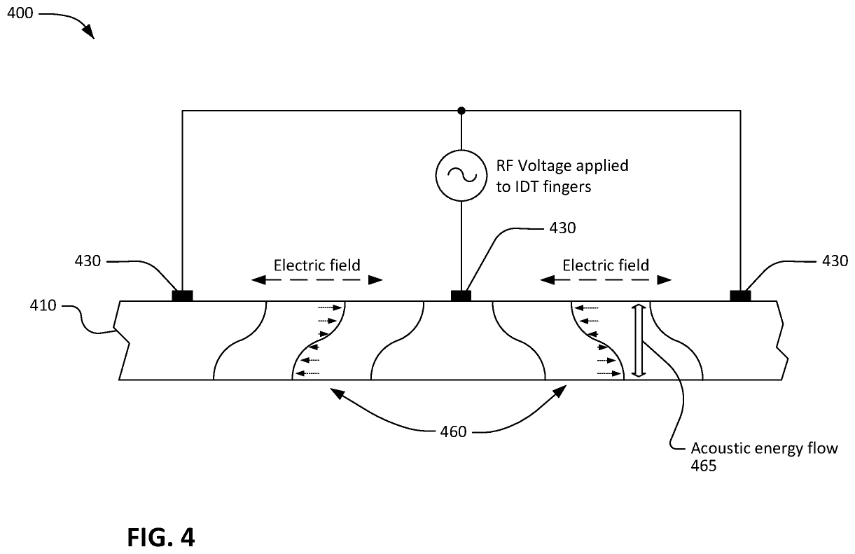

In general, the IDT of an XBAR differs substantially from the IDTs used in surface acoustic wave (SAW) resonators, primarily in that IDTs of an XBAR excite a shear thickness mode, as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front-side and back-side dielectric layers 212, 214 disposed thereon. In an exemplary aspect, the thickness of one or both dielectric layers can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and, thus a thinner overall thickness.

Referring back to FIG. 2A, the thickness tfd of the front-side dielectric layer 212 over the IDT fingers 238a, 238b may be greater than or equal to a minimum thickness required to deal and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back-side dielectric layer 214 may be configured to a specific thickness to adjust the resonance frequency of the resonator as will be described in more detail below.

Although FIG. 2A discloses a configuration in which IDT fingers 238a and 238b are on the front side 112 of the piezoelectric layer 110, alternative configurations can be provided. For example, FIG. 2B shows an alternative configuration in which the IDT fingers 238a, 238b are on the back side 114 of the piezoelectric layer 110 (i.e., facing the cavity) and are covered by a back-side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b on the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration in which IDT fingers 238a, 238b are on the front side 112 of the piezoelectric layer 110 and are covered by a front-side dielectric layer 212. IDT fingers 238c, 238d are also on the back side 114 of the piezoelectric layer 110 and are also covered by a back-side dielectric layer 214. As previously described, the front-side and back-side dielectric layer 212, 214 are not necessarily the same thickness or the same material.

FIG. 2D shows another alternative configuration in which IDT fingers 238a, 238b are on the front side 112 of the piezoelectric layer 110 and are covered by a front-side dielectric layer 212. The surface of the front-side dielectric layer is planarized. The front-side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM XBAR). The SM XBAR includes a piezoelectric layer 110 and an IDT (of which only fingers 238 are visible) with a dielectric layer 212 disposed on the piezoelectric layer 110 and IDT fingers 238. The piezoelectric layer 110 has parallel front and back surfaces similar to the configurations described above. Dimension ts is the thickness of the piezoelectric layer 110. The width of the IDT fingers 238 is dimension w, thickness of the IDT fingers is dimension tm, and the IDT pitch is dimension p.

In contrast to the XBAR devices shown in FIG. 1, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 238, may be disposed on the front surface of the piezoelectric layer 110. Alternatively, IDT fingers, such as IDT finger 238, may be disposed in grooves formed in the front surface. The grooves may extend partially through the piezoelectric layer. Alternatively, the grooves may extend completely through the piezoelectric layer.

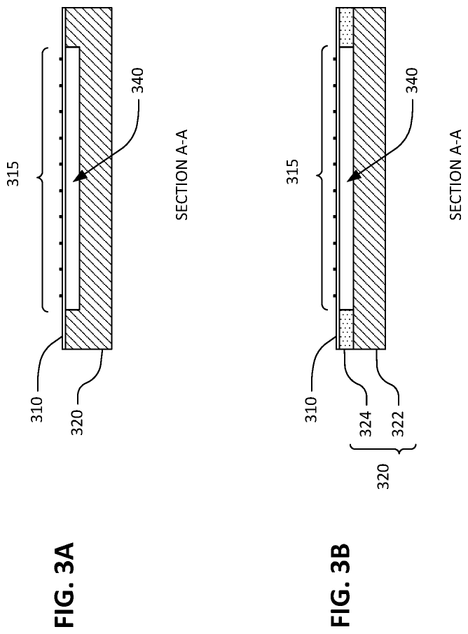

FIG. 3A and FIG. 3B show two exemplary cross-sectional views along the section plane A-A defined in FIG. 1 of XBAR 100. In FIG. 3A, a piezoelectric layer 310, which corresponds to piezoelectric layer 110, is attached directly to a substrate 320, which can correspond to substrate 120 of FIG. 1. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIG. 1 in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In some cases, the etching may be performed with a selective etchant that reaches the substrate through one or more openings (not shown) provided in the piezoelectric layer 310.

In this case, the diaphragm 315, which can correspond to diaphragm 115 of FIG. 1 in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may extend into, but not though the intermediate layer 324 (i.e., the intermediate layer 324 may extend over the bottom of the cavity on top of the base 322), or may extend through the intermediate layer 324 into the base 322.

FIG. 4 is a graphical illustration of the primary acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2E according to an exemplary aspect. Thus, it should be appreciated that piezoelectric layer 410 can correspond to piezoelectric layer 110 and IDT fingers 430 can be implemented according to any of the configurations of fingers 238, 238a and 238b, for example.

In operation, an RF voltage is applied to the interleaved fingers 430. This voltage creates a time-varying electric field between the fingers. The direction of the electric field is lateral, or parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the excited primary shear acoustic mode is substantially orthogonal to the surface of the piezoelectric layer, as indicated by the arrow 465.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

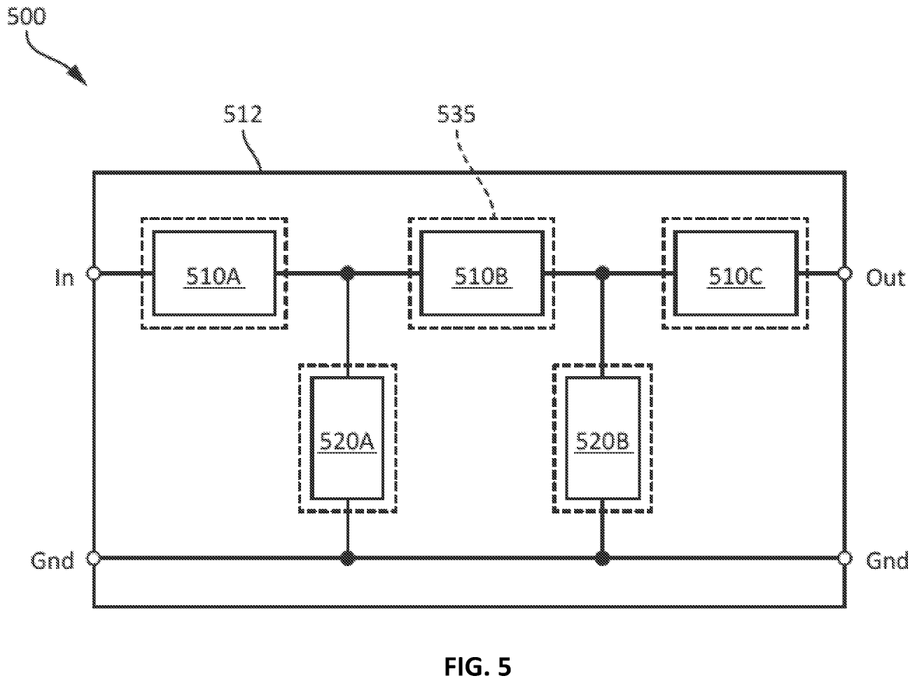

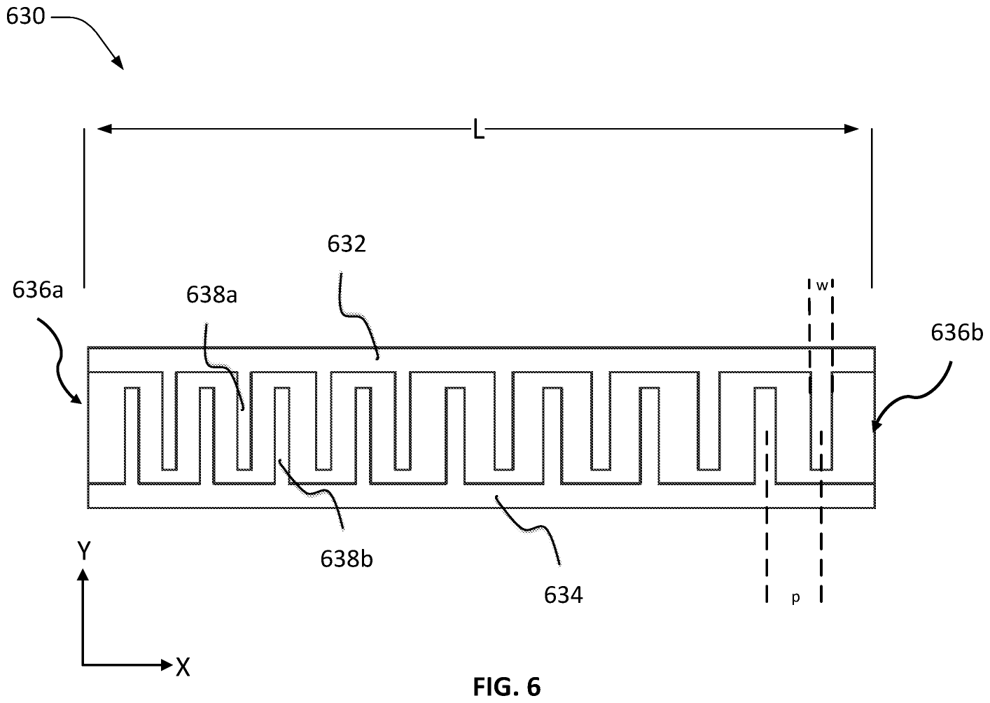

FIG. 5 is a schematic circuit diagram and layout for a high frequency band-pass filter 500 using XBARs, such as the general XBAR configuration 100 described above, for example. The filter 500 has a conventional ladder filter architecture including three series resonators 510A, 510B, and 510C and two shunt resonators 520A and 520B. The series resonators 510A, 510B and 510C are connected in series between a first port and a second port (hence the term “series resonator”). In FIG. 5, the first and second ports are labeled “In” and “Out”, respectively. However, the filter 500 is bidirectional and either port may serve as the input or output of the filter. The shunt resonators 520A and 520B are connected from nodes between the series resonators to ground. A filter may contain additional reactive components, such as inductors, not shown in FIG. 5. All the shunt resonators and series resonators are XBARs. The inclusion of three series and two shunt resonators is an example. A filter may have more or fewer than five total resonators, more or fewer than three series resonators, and more or fewer than two shunt resonators. Typically, all of the series resonators are connected in series between an input and an output of the filter. All of the shunt resonators are typically connected between ground and the input, the output, or a node between two series resonators.

In the exemplary filter 500, the series resonators 510A, 510B and 510C and the shunt resonators 520A and 520B of the filter 500 are formed on at least one, and in some cases a single, layer 512 of piezoelectric material bonded to a silicon substrate (not visible). Each resonator includes a respective IDT (not shown), with at least the fingers of the IDT disposed over a cavity in the substrate. In this and similar contexts, the term “respective” means “relating things each to each,” which is to say with a one-to-one correspondence. In FIG. 5, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 520A and 520B in the filter 500 has a resonance where the admittance of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 520A and 520B may have a particular coupling parameter to which the respective resonator is tuned in order to achieve the required frequency response of the filter 500.

According to an exemplary aspect, each of the series resonators 510A, 510B, and 510C and the shunt resonators 520A and 520B can have an XBAR configuration as described above with respect to FIGS. 1-3 in which a diaphragm with IDT fingers spans over a cavity, except for FIG. 2E for an SM XBAR. That is, each of the series resonators 510A, 510B, and 510C and the shunt resonators 520A and 520B can also have the XM XBAR configuration of FIG. 2E in an alternative aspect.

As generally described above, the primary acoustic mode of the piezoelectric layer of an XBAR is mostly bulk (i.e., a shear bulk wave) in nature, which can result in weak frequency dependence on mark and pitch. Thus, chirping (which is a periodic or continued variance) of mark (i.e., the IDT finger width and pitch (i.e., the center-to-center spacing between adjacent interleaved fingers) in the IDT of the XBAR potentially suppresses undesirable spurious modes that depend upon mark and/or pitch, such as metal and propagating modes, with only slight broadening of the primary mode resonance. In particular, as described as follows, the exemplary aspects of the acoustic resonator vary the mark and pitch of the fingers along the length of the IDT to spread out the impact of spurs on the resonance response.

FIG. 6 is an expanded cross-sectional view of an IDT configuration with balanced chirping of an XBAR of according to an exemplary aspect. In general, the IDT 630 corresponds to a similar structure as described above for the XBAR shown in FIG. 1. Moreover, the IDT 630 can be disposed on a diaphragm over a cavity (e.g., as described with respect to any of FIGS. 2A to 2D) or alternatively an SM-XBAR configuration as shown in FIG. 2E and described above. It should be appreciated that only the conductive pattern of the IDT itself is shown in FIG. 6 without the piezoelectric layer (e.g., diaphragm), cavity, substrate, and the like.

As shown, the IDT 630 includes a first plurality of parallel electrode fingers, including finger 638a, extending from a first end of the first busbar 632 to a second end of the first busbar 632. Similarly, the IDT 630 also includes a second plurality of electrode fingers, including finger 638b, extending from a first end of a second busbar 634 to a second end of the second busbar 634. The first and second pluralities of parallel fingers are interleaved with each other as described above. The IDT 630 generally extends in a plane defined by the X-Y axes. For purposes of this disclosure, the X direction (e.g., a first direction) is shown as a lengthwise direction of the IDT and the Y direction (e.g., a second direction) is shown as a widthwise direction. Thus, the first and second plurality of electrode fingers extend across the piezoelectric layer of the acoustic resonator in the plane defined by the X and Y axes. The Z axis (not shown) extends in the thickness direction and orthogonal to the X and Y axes.

Moreover, the center-to-center distance L between the outermost fingers of the IDT 630 is the “length” of the IDT, which extends in the X direction or lengthwise direction of the IDT 630. In the exemplary aspect, the pair of busbars 632 and 634 also extend in the X direction or lengthwise direction of the IDT 630. The first plurality of fingers (including finger 638a) extends generally perpendicularly from busbar 632 in the Y direction or widthwise direction of the IDT 630. Similarly, the second plurality of fingers (including finger 638b) extend generally perpendicularly from busbar 634 in the Y direction or widthwise direction of the IDT 630. Thus, the first and second plurality of fingers generally traverse (or extend) across the diaphragm of the piezoelectric layer/plate from a first end 636a of the IDT 630 to a second end 636b of the IDT 630. It should be appreciated that the first and second ends 636a and 636b are identified based on the orientation of the IDT 630 as shown in FIG. 6, but could be reversed based on an alternative orientation of the XBAR device as a whole.

The first and second plurality of interleaved fingers may extend in opposite directions towards each other to establish the interleaved configuration. For purposes of this disclosure, the term “perpendicular” is not limited only to a strictly perpendicular case and can be substantially perpendicular (e.g., an angle formed between the direction perpendicular to the length direction of the interleaved fingers and the polarization direction can be, for example, about 90°+10°). Such variations can be a result of manufacturing variances or tolerances, for example. Thus, in a general configuration, the busbars will extend in a first direction and the interleaved fingers will extend in a second direction that intersects the first direction and is not necessarily periodical to one another.

As described above, the electrodes (e.g., fingers 638a and 638b) can be interdigitated with each other. As further shown, the interleaved fingers each can have a rectangular shape and can have a length direction (extending in the Y direction). Thus, IDT 630 is defined by the first and second plurality of interleaved fingers, the first busbar 632, and the second busbar 634. The length direction of the interleaved fingers (i.e., the Y direction) and the direction perpendicular to the length direction of the electrodes (i.e., the X direction) are both directions that intersect with a thickness direction of the diaphragm.

In an exemplary aspect, pairs of adjacent electrodes (e.g., finger 638a and an adjacent finger) are connected to one potential and electrodes (e.g., finger 638b and an adjacent finger) are connected to the other potential and are provided in the direction perpendicular to the length direction of the electrodes. As generally described above, in operation, a radio frequency or microwave signal applied between the two busbars 632, 634 of the IDT 630 excites a primary shear acoustic mode within the piezoelectric layer (not shown in FIG. 6).

As generally described above, chirping is the variation of the mark or pitch or both over the resonator length and causes both spurs and the main resonance to spread in frequency. The spreading of the main resonance may be an associated undesirable effect as it may increases loss near resonance. According to the exemplary aspect of FIG. 6, the IDT 630 implements both mark and pitch chirping in a way in which the frequency shift of the main mode cancels. Moreover, the spur sensitivity to the mark and pitch changes is different than for the main mode, and their frequency shift does not cancel. As a result, this configuration chirps spurs while avoiding increased loss near resonance.

It should also be appreciated that mark chirp is the change in mark between adjacent interleaved fingers. In some embodiments, the change in mark changes at a constant rate, although in other embodiments, change in the mark may occur in discrete sections where each section has a constant average mark, a continually changing mark, or any combination thereof within the section different than another section. For example, the IDT may include a plurality of sections of interleaved fingers, for example, five pairs of interleaved fingers per section. The interleaved fingers of each section may have the same mark, but then the marks of the interleaved fingers of the next section may be slightly larger than the first section and so forth.

Similarly, pitch chirp is the change in pitch between adjacent interleaved fingers the length of the IDT. In some embodiments, the change in pitch changes at a constant rate, although in other embodiments, change in the pitch may occur in discrete sections where each section has a constant average pitch, a continually changing pitch, or any combination thereof within the section different than another section. Similar to the configuration described above, the IDT may include a plurality of sections of interleaved fingers, for example, five pairs of interleaved fingers per section. The interleaved fingers of each section may have a first pitch, but then the pitch of the interleaved fingers of the next section may be slightly smaller than the first section and so forth.

In either case, each acoustic resonator with balanced chirping will have a mark chirp to pitch chirp ratio, which is effectively the rate of mark chirping to the rate of pitch chirping.

As further shown in FIG. 6, the mark (i.e., width “w”) of the interleaved fingers are measured in the lengthwise (i.e., the X direction) of the IDT 630. In this aspect, the mark of the interleaved fingers of both the first plurality of interleaved fingers extending from busbar 632 and the second plurality of interleaved fingers extending from busbar 632 increases (i.e., is chirped) from the first end 636a to the second end 636b of the IDT 630. According to one exemplary aspect, the marks of the interleaved fingers are chirped continuously from the first end 636a to the second end 636b of the IDT 630. In other words, each mark (width “w”) slightly increases as the plurality of interleaved fingers transverse across the diaphragm. In another aspect, the marks of the interleaved fingers are chirped periodically from the first end 636a to the second end 636b of the IDT 630. That is, the IDT may have a plurality of sections (e.g., two or more interleaved fingers) with section having a constant mark and the next section increasing and so forth. It is noted that while the exemplary aspect illustrates the marks of the interleaved fingers increasing from first end 636a to second send 636b, this configuration may be reversed in an alternative aspect.

As further shown in FIG. 6, the pitch “p” (i.e., center-to-center spacing between adjacent electrodes) of the interleaved fingers are also measured in the lengthwise (i.e., the X direction) of the IDT 630. In this aspect, the pitch of the interleaved fingers extending from busbars 632 and 634 decreases (i.e., is chirped) from the first end 636a to the second end 636b of the IDT 630. In other words, the pitch (i.e., the center-to-center spacing) between two adjacent electrode fingers closer to the first end 636a will be greater than the pitch (i.e., the center-to-center spacing) between two adjacent electrode fingers closer to the second end 636b. As a result, while the mark of the fingers increases from first end 636a to the second end 636b, the pitch of the interleaved fingers decreases from the first end 636a to the second end 636b, which creates for a balanced chirping of the IDT 630 as a whole for the exemplary acoustic resonator.

According to one exemplary aspect, the pitches of the interleaved fingers are chirped continuously from the first end 636a to the second end 636b of the IDT 630. In other words, the pitch “p” slightly decreases at a constant rate as the plurality of interleaved fingers transverse across the diaphragm. In another aspect, the pitches of the interleaved fingers are chirped periodically from the first end 636a to the second end 636b of the IDT 630. That is, the IDT may have a plurality of sections (e.g., two or more pairs of interleaved fingers) with each section having a constant pitch and the next section decreasing and so forth. It is noted that while the exemplary aspect illustrates the pitches of the interleaved fingers decreasing from first end 636a to second send 636b, this configuration may be reversed in an alternative aspect as long as the chirping is opposite configuration (e.g., direction) from the chirping of the mark of the interleaved fingers. That is, the mark chirping increases in a first direction (e.g., a positive direction) that is inversely configured relative to the pitch chirping, which increases in a second direction (e.g., a negative direction) relative to the first direction of the mark chirping.

According to the exemplary configuration shown in FIG. 6, the chirping configuration of both the mark and pitch of the interleaved fingers of the IDT 630 (or a portion of the interleaved fingers) is provided in way in which the frequency shift of the main mode cancels. That is, at least some or all of a portion of the interleaved fingers may be mark chirped to cancel certain spurs of the frequency response. However, such mark chirping will typically cause a shift in the resonant frequency of the resonator. Thus, the exemplary aspects address this frequency shift by also pitch chirping the same portion of interleaved fingers of the IDT, such that the frequency change of the primary mode of the resonator due to the mark pitching is canceled out. In other words, the mark chirping may cause a frequency shift in a first direction so the pitch chirping will be set to shift the frequency in the second and opposite direction, preferably by at least 50% back to cancel out at least a portion of the frequency shift. In other words, the mark chirping and pitch chirping of the same portion (some or all) of the interleaved fingers of the IDT of the resonator are balanced.

When mark and pitch chirping is balanced, the sign and extent of the mark chirp is chosen (e.g., use a negative mark chirp as compared to a positive chirp of the pitch) to cancel out the frequency shift of the main mode due to the pitch chirp. Practically this means that the ratio of the size of the chirps must be a particular value, such as a ratio that would create the same change in the frequency shift of the main mode so that when one of the chirps is reversed in sign, they cancel out any change in the main mode. The spur sensitivity to the mark and pitch changes is different than for the main mode (e.g., different than for the main resonance), and the spur frequency shift does not cancel. In this way spurs may be chirped to spread out the impact of spurs on the filter response while avoiding increased loss near resonance. It should be appreciated that while the exemplary embodiment describes pitch chirping increasing while mark chirping decreases across the length (or a portion thereof) of the IDT, the mark and pitch chirping may both increase or decrease along the same portion of interleaved fingers in an alternative aspect as long as the chirping is balanced, i.e., the sum of frequency shifts due to the respective chirping is canceled out by at least 50%.

It should also be appreciated that while the exemplary embodiment describes the mark of the electrode fingers increasing (either sectionally or continuously) from a first end of the IDT to a second end of the IDT, the increase in mark may only occur for a portion of the length of the IDT. For example, the mark may increase from a first end of the IDT to a middle point of the IDT (e.g., over a center of the diaphragm) and then begin to decrease back towards the second end of the IDT. In one exemplary aspect, the IDT may have five sections of interleaved fingers. In this example, the first section (e.g., five pairs of interleaved fingers) may have interleaved fingers with a mark δ. The second section (e.g., five pairs of interleaved fingers) may have interleaved fingers with a mark δ+Δ (where Δ represents a slight increase in overall width). The third section (e.g., five pairs of interleaved fingers) may have interleaved fingers with a mark δ+2Δ, such that this middle section has interleaved fingers with the largest mark. The IDT will then be symmetrical where the fourth section (e.g., five pairs of interleaved fingers) will also have interleaved fingers with a mark δ+Δ and the first section (e.g., five pairs of interleaved fingers) will have interleaved fingers with a mark S. As a result, the IDT will have a symmetrical mark chirping that increases to the middle of the IDT and then decreases towards each end of the IDT.

Similarly, it should be appreciated that in this configuration, the pitch of the interleaved fingers will be inversely related. That is, the pitch will decrease towards the middle of the IDT and then increase towards each end of the IDT. Thus, the mark chirping ratio and pitching chirping ratio of such an IDT will be inversely related. In an alternative aspect, the IDT may have the opposite configuration where the mark chirping decreases towards the center of the IDT whereas the pitch chirping increases towards the center of the IDT.

As such, the exemplary aspects include configurations where the respective widths of at least a portion of the electrode fingers of the first and second plurality of electrode fingers (extending from the respective busbars) increases (or decreases in the alternative) in a direction from the respective first ends of the first and second busbars to the respective second end of the first and second busbars. Likewise, but according to an inverse relationship, the pitch of the same portion of the electrode fingers decreases (or increases in the alternative) in the direction from the respective first ends of the first and second busbar to the respective second ends of the first and second busbars. Further, a first portion of the electrode finger widths may increase while the pitch decreases and a second portion of the electrode finger widths may decrease while pitch increases. Any of these configurations within a resonator, within a filter, or combination thereof may provide for a balanced configuration of the IDT as a whole as described herein.

Referring now back to FIG. 5, a high frequency band-pass filter 500 using XBARs with balanced chirping as described herein can be provided in an exemplary aspect. In particular, the filter 500 has a ladder filter architecture including three series resonators 510A, 510B, and 510C and two shunt resonators 520A and 520B. In an exemplary aspect, each of these resonators can have the same configuration or varying configurations of the IDT 630 described above to provide for balanced chirping.

In particular, a filter device 500 can be provided with a substrate, one or more piezoelectric layers supported by the substrate, and a plurality of interdigital transducers (IDTs) at a surface of the at least one piezoelectric layer. Each IDT can be formed from a conductor pattern to have a balanced chirping configuration. For example, each IDT can include a first busbar and a second busbar that each extend in a first direction from a first end to a second end thereof, a first plurality of electrode fingers that extend from the first busbar in a second direction towards to the second busbar, with the second direction intersecting the first direction, and a second plurality of electrode fingers extending from the second busbar in the second direction towards to the first busbar, such that the first and second plurality of electrode fingers are interleaved with each other.

Moreover, in an exemplary aspect, a first IDT of the plurality of IDTs can have respective widths of the electrode fingers of the first plurality of electrode fingers that increase at a first rate (i.e., a constant rate of increase) in a direction from the first end of the first busbar to the second end of the first busbar. Moreover, a second IDT of the plurality of IDTs can have respective widths of the electrode fingers of the first plurality of electrode fingers increases at a second rate (i.e., a constant rate of increase) in the direction from the first end of the first busbar to the second end of the first busbar.

In this aspect, the first rate is different than the second rate, meaning that the mark chirp is different between two or more of the resonators of the filter device. As a result, the rate of mark chirping can be selected and tuned to improve the overall frequency response of the filter device.

Furthermore, in an exemplary aspect, a pitch of the interleaved fingers of the first IDT can decrease in the direction from the first end of the first busbar to the second end of the first busbar. Similarly, a pitch of the interleaved fingers of the second IDT decreases in the direction from the first end of the first busbar to the second end of the first busbar. The pitch chirping of each of the resonators of the filter device can be configured at a same rate or different rates between two or more of the acoustic resonators. Again, the filter device can be configured such that each individual resonator uses both mark and pitch chirping in a balanced configuration to cancel the frequency shift of the main mode. In general, according to the exemplary aspects, the electrode finger center-center spacing (i.e., the pitch chirping) and the electrode width (i.e., the mark chirping) will vary over the resonator length for each acoustic resonator, which will typically be a few percent, such as less than 10% total variation from the first end to the second end of the IDT.

According to an exemplary aspect, the entire filter device can be tuned such that each individual resonator of the filter has a different balanced chirping configuration. For example, a first resonator can have a first mark chirp to pitch chirp ratio and a second resonator can have a second mark chirp to pitch chirp ratio that is different than the first ratio, but again where each ratio still implements the balanced chirping configuration described herein. More particular, a first IDT of the plurality of IDTs can have a first ratio of mark chirp to pitch chirp of the electrode fingers of the first and second pluralities of the electrode fingers of the first IDT, and a second IDT of the plurality of IDTs can have a second ratio of mark chirp to pitch chirp of the electrode fingers of the first and second pluralities of the electrode fingers of the second IDT, with the second ratio being different than the first ratio. These differing ratios can be selected so that the resonant frequency of each resonator does not change while spurs of the filter device as a whole are spread out.

Thus, according to the exemplary aspects of the filter device, for a first acoustic resonator, one of either of the mark chirp or the pitch chirp of its first IDT will be selected to spread out a spur impact of a frequency response in a primary mode of the acoustic resonator. To provide balanced chirping the other of the mark chirp and the pitch chirp of the resonator's IDT will be selected and configured to at least partially (e.g., 50% or greater) cancel a change of the frequency response in the primary mode of the first acoustic resonator. Similar balanced chirping configurations can be implemented for each acoustic resonator of the filter device.

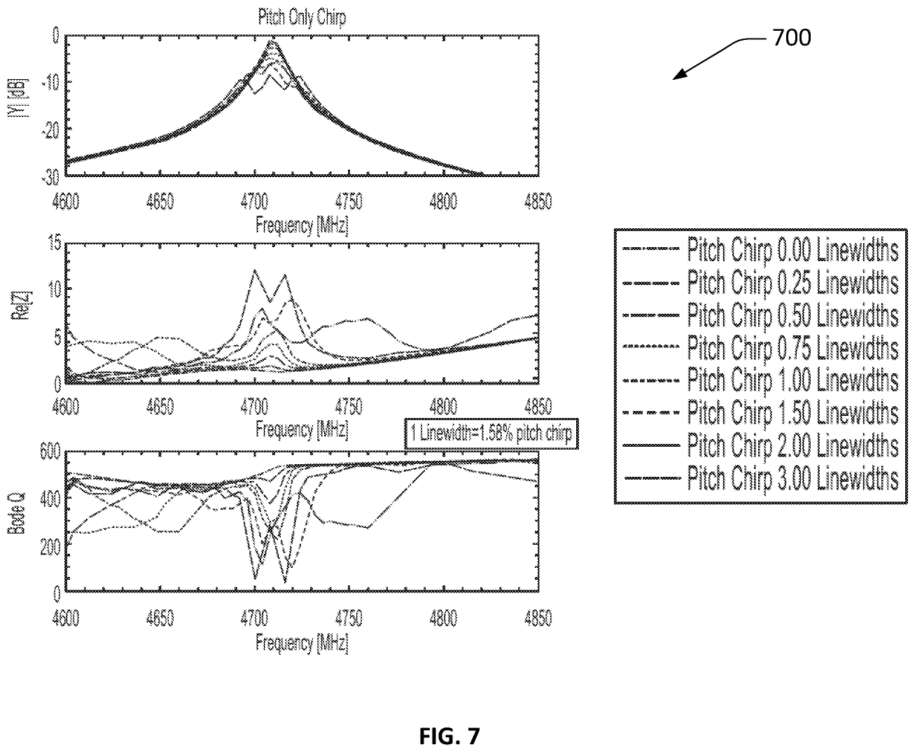

FIGS. 7 to 9 are graphs showing the resonant characteristics with pitch chirping, mark chirping, and pitch and mark chirping (i.e., balanced chirping) according to exemplary aspects. The data illustrated in graphs 700, 800 and 900 was determined by simulation of the acoustic resonators and filter devices using a finite element method. The design parameters of the acoustic wave device for the simulations are as follows. The piezoelectric layer is made of lithium niobate and has a thickness of about 400 nm, for example. The metal (i.e., the conductive patterns for the IDT) has a thickness of 1.25 times the thickness of the piezoelectric layer. There are no oxide layers. The average mark was 2.49 times the thickness of the piezoelectric layer. The average pitch was 10 times the thickness of the piezoelectric layer.

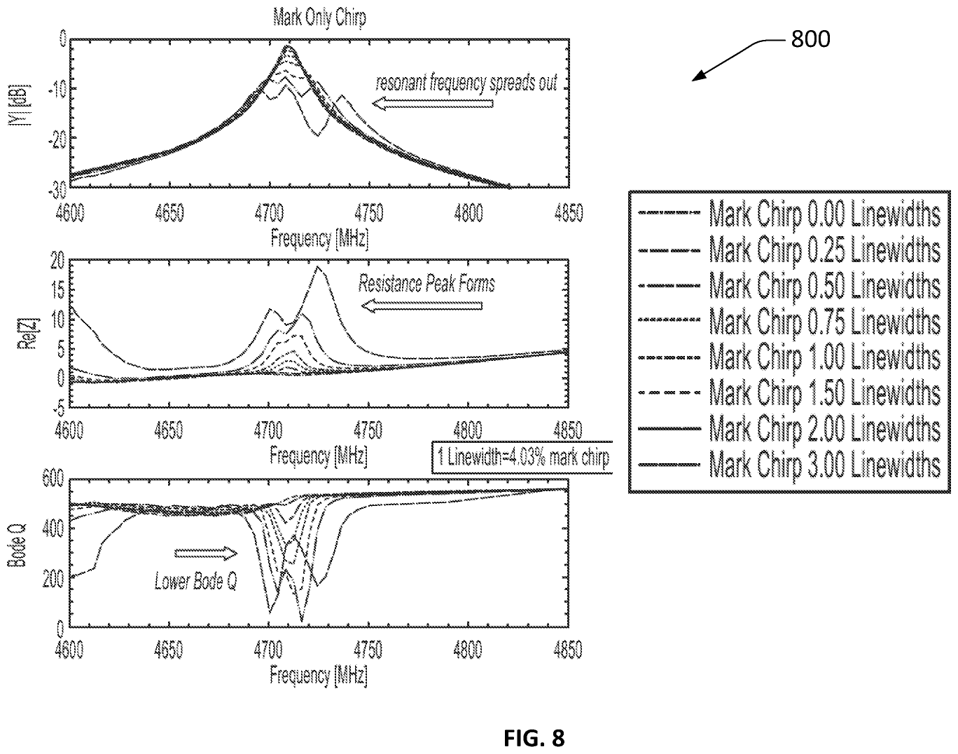

FIG. 7 illustrates a graph 700s with pitch only chirping according to an exemplary aspect whereas FIG. 8 illustrates a graph 800s with mark only chirping according to an exemplary aspect. As shown in these simulations, the configurations provide for a lower Bode Q, which is a measurement of the resonator's response. That is, when mark and pitch of the acoustic resonator are chirped individually (or together but in an unbalanced manner), the resonant frequency of the main mode spreads out. Moreover, a resistance peak forms around the resonant frequency, and the Bode Q falls, which are undesirable effects that increase loss of the filter device.

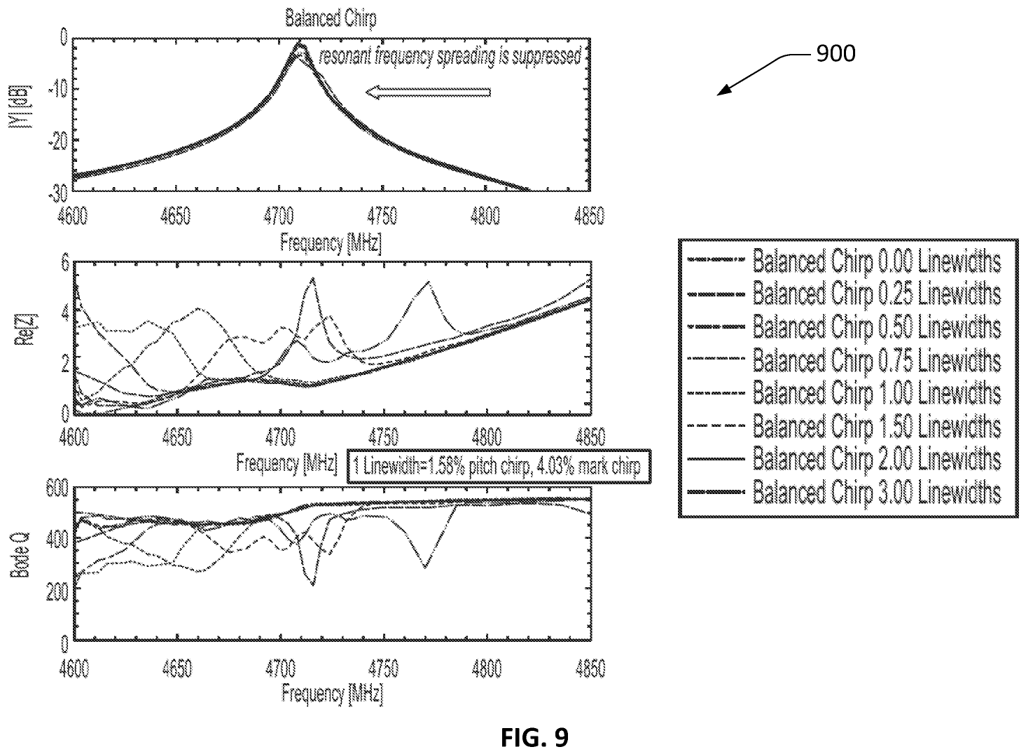

In contrast, FIG. 9 illustrates a graph 900s with a balanced chirping according to an exemplary aspect. When mark and pitch chirping is balanced as described according to the configurations above, the sign and extent of the mark chip can be selected to cancel out the frequency shift of the main mode due to the pitch chirp. Practically, this means that the ratio (i.e., the mark chirp to pitch chirp ratio) of the size of the chirps can be selected as a particular value. As noted above, the example shown includes the dimensions of a 400 nm LN piezoelectric layer, a metal thickness of 1.25 times the thickness of the piezoelectric layer, an average mark of 2.49 times the thickness of the piezoelectric layer, and an average pitch of 10 times the thickness of the piezoelectric layer. As illustrated from graphs 900, a pitch change of −1.58% (˜1.60%) caused the same frequency shift as a mark change of −4.03% (˜4.0%). In this example, to cancel out the frequency shift, the mark chirping was applied with opposite sign, i.e., there is a −1.58% pitch change and a +4.03% mark change over the length of the resonator. Effectively, the mark chirp to pitch chirp ratio is −1.60% to 4.00%. In alternative aspects, the mark and pitch chirping may vary been ±10% along the length of the IDT and will be set based on the desired frequency response, variable dimensions (e.g., thicknesses of the piezoelectric layer and IDT fingers), and the like. In such configurations, when the ratio of the chirps remains the same and the value of the chirps is not so large that the linear frequency shift approximation breaks down, the chirping will be balanced. In the exemplary configuration, the balancing is effective up one resonant linewidth of shift as shown in the graphs 900. For purposes of this disclosure, a “linewidth” is a measure of how sharp a resonance is and is related to the Q factor of the resonator. Referring to FIG. 9, for example, the linewidth can be typically defined as the width of the resonance peak measured 3 dB down from the peak (e.g., the curve peak shown in the admittance (y[db]) plot of graph 900. The linewidth is related to the resonance Q by the relationship Q=resonance frequency/linewidth. For example, a resonance at 5 GHz with a Q of 1000 will have a 5 MHz linewidth. In the context of exemplary aspects described herein, the “linewidth” illustrates how much the resonance may move without significant spreading of the peak or equivalently how much the mark and/or pitch can be chirped without suffering a penalty in resistance. In general, if a chirp is implemented so that the resonance moves 1 linewidth or less, the peak moves substantially into a frequency range where it did not exist without chirping. This is visible in the response as significant spreading around the resonance peak.

Accordingly, the exemplary acoustic resonator configuration provides for a balanced chirping that suppresses the frequency broadening of the main resonance, the resistance peak caused by unbalanced chirping, and the lowering of the BodeQ. Effectively, the IDT configuration restores these parameters to unchirped levels. In other words, with balanced chirping according to the exemplary aspects described herein, the absolute change in mark and pitch may be substantially increased to, for example, 3× the absolute mark or pitch change, with an often larger effect on spurs because the combined change of frequency remains close to zero. Balanced chirping can be considered a “3 linewidth” balanced chirp, even though the frequency does not move to indicate the change of frequency that would have occurred had the chirp not been balanced, as illustrated in FIG. 9. It should also be appreciated that while the change in frequency according to a balanced configuration is zero in a perfectly balanced chirp, often manufacturing and design constraints and variances may impose some amount of imbalance that results in some amount of change to frequency change, which will be tolerable (as explained above) as long as the frequency change 1 linewidth or less.

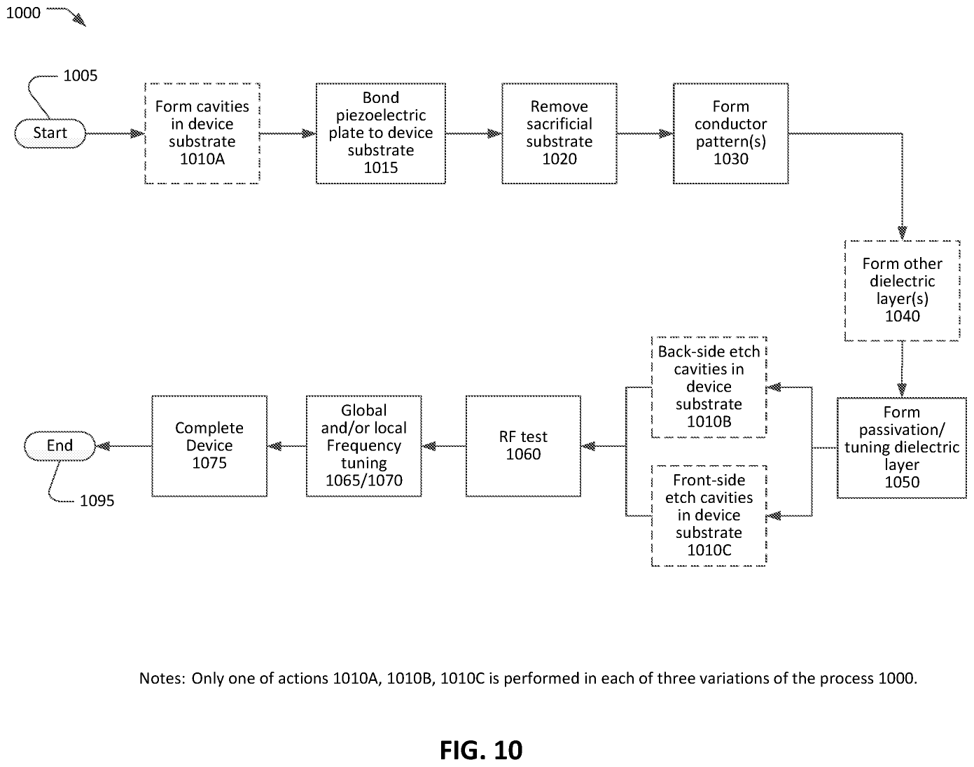

FIG. 10 illustrates a flowchart of a method of manufacturing a filter as described herein according to an exemplary aspect. In particular, method 1000 summarizes an exemplary manufacturing processing for fabricating a filter device incorporating XBARs as described herein. Specifically, the process 1000 is for fabricating a filter device including multiple XBARs having a balanced chirping configuration a described herein. The process 1000 starts at 1005 with a device substrate and a thin layer of piezoelectric material disposed on a sacrificial substrate. The process 1000 ends at 1095 with a completed filter device. The flow chart of FIG. 10 includes only major process steps. Various conventional process steps (e.g., surface preparation, cleaning, inspection, baking, annealing, monitoring, testing, etc.) may be performed before, between, after, and during the steps shown in FIG. 10.

While FIG. 10 generally describes a process for fabricating a single filter device, multiple filter devices may be fabricated simultaneously on a common wafer (including a piezoelectric layer bonded to a substrate). In this case, each step of the process 1000 may be performed concurrently on all of the filter devices on the wafer.

The flow chart of FIG. 10 captures three variations of the process 1000 for making an XBAR which differ in when and how cavities are formed in the device substrate. The cavities may be formed at steps 1010A, 1010B, or 1010C. Only one of these steps is performed in each of the three variations of the process 1000. It should be appreciated that these steps can be omitted if the filter device comprises only SM XBARs configurations, for example. In such an embodiment, separate steps (not shown) for forming the layers of the Bragg mirror may be incorporated into the exemplary manufacturing method.

In an exemplary aspect, the piezoelectric layer may typically be Z-cut or 82Y-cut lithium niobate. The piezoelectric layer may be some other material and/or some other cut. The device substrate may preferably be silicon. The device substrate may be some other material that allows formation of deep cavities by etching or other processing.

In one variation of the process 1000, one or more cavities are formed in the device substrate at 1010A, before the at least one piezoelectric layer is bonded to the substrate at 1015. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities may be formed using conventional photolithographic and etching techniques. Typically, the cavities formed at 1010A will not penetrate through the device substrate.

At 1015, the at least one piezoelectric layer is bonded to the device substrate or indirectly to a dielectric layer as described above. The at least one piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 1020, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1020, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

A first conductor pattern, including IDTs of each XBAR, is formed at 1030 by depositing and patterning one or more conductor layers on the front side of the piezoelectric layer. The conductor layer may be, for example, aluminum, an aluminum alloy, copper, a copper alloy, or some other conductive metal. In some aspects, one or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer. A second conductor pattern of gold, aluminum, copper or other higher conductivity metal may be formed over portions of the first conductor pattern (for example the IDT bus bars and interconnections between the IDTs).

Each conductor pattern may be formed at 1030 by depositing the conductor layer and, in some aspects, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1030 using a lift-off process. Photoresist may be deposited over the piezoelectric layer and patterned to define the conductor pattern. It should be appreciated that the photoresist for the conductor pattern can be defined to achieve the desired chirping configurations as described above. Moreover, the conductor layer and, in some aspects, one or more other layers may be deposited in sequence over the surface of the piezoelectric layer. The photoresist may then be removed, which removes the excess material, leaving the conductor pattern.

At 1040, one or more dielectric layers may be formed on one or both surfaces of the piezoelectric layer and conductor patterns. These layers can be deposited and trimmed to configure the resonant frequency according to exemplary aspects.

At 1050, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 1000, the passivation/tuning dielectric layer may be formed after the cavities in the device substrate are etched at either 1010B or 1010C.

In a second variation of the process 1000, one or more cavities are formed in the back side of the device substrate at 1010B. A separate cavity may be formed for each resonator in a filter device. Also, the cavities can be shaped and formed such that plurality of resonators can be on one diaphragm over one cavity. These resonators sharing a diaphragm are acoustically coupled on an acoustic track. The one or more cavities may be formed using an anisotropic or orientation-dependent dry or wet etch to open holes through the back side of the device substrate to the piezoelectric layer. In this case, the resulting resonator devices will have a cross-section as shown in FIG. 1.

In a third variation of the process 1000, one or more cavities in the form of recesses in the device substrate may be formed at 1010C by etching the substrate using an etchant introduced through openings in the piezoelectric layer. A separate cavity may be formed for each resonator in a filter device. Also, the cavities can be shaped and formed such that two or more resonators can be on one diaphragm over one cavity. These resonators sharing a diaphragm are acoustically coupled on an acoustic track. The one or more cavities formed at 1010C will not penetrate through the device substrate.

Ideally, after the cavities are formed at 1010B or 1010C, most or all of the filter devices on a wafer will meet a set of performance requirements. However, normal process tolerances will result in variations in parameters such as the thicknesses of dielectric layers formed at 1040 and 1050, variations in the thickness and line widths of conductors and IDT fingers formed at 1030, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1050. The frequency of a filter device passband can be lowered by adding material to the passivation/tuning layer, and the frequency of the filter device passband can be increased by removing material from the passivation/tuning layer. Typically, the process 1000 is biased to produce filter devices with passbands that are initially lower than a required frequency range but can be tuned to the desired frequency range by removing material from the surface of the passivation/tuning layer.

At 1060, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1065, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1060 may be processed to generate a global contour map indicating the amount of material to be removed as a function of two-dimensional position on the wafer. The material is then removed in accordance with the contour map using the selective material removal tool.

At 1070, local frequency tuning may be performed in addition to, or instead of, the global frequency tuning performed at 1065. “Local” frequency tuning is performed with a spatial resolution smaller than an individual filter device. The test results from 1060 may be processed to generate a map indicating the amount of material to be removed at each filter device. Local frequency tuning may require the use of a mask to restrict the size of the areas from which material is removed. For example, a first mask may be used to restrict tuning to only shunt resonators, a second mask may be subsequently used to restrict tuning to only series resonators, and a third mask may be subsequently used to restrict tuning to only extracted pole resonators. This would allow independent tuning of the lower band edge and upper band edge of the filter devices.

After frequency tuning at 1065 and/or 1070, the filter device is completed at 1075. Actions that may occur at 1075 include forming bonding pads or solder bumps or other means for making connection between the device and external circuitry (if such pads were not formed at 1030); excising individual filter devices from a wafer containing multiple filter devices; other packaging steps; and additional testing. After each filter device is completed, the process ends at 1095.

In general, it is noted that throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, the pair of terms “top” and “bottom” can be interchanged with the pair “front” and “back”. As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator comprising:
a substrate;
a piezoelectric layer supported by the substrate; and
an interdigital transducer (IDT) at a surface of the piezoelectric layer, the IDT including:
a first busbar and a second busbar that each extend in a first direction from a first end to a second end thereof,
a first plurality of electrode fingers extending from the first busbar in a second direction towards the second busbar, with the second direction intersecting the first direction, and
a second plurality of electrode fingers extending from the second busbar in the second direction towards to the first busbar, such that the first and second plurality of electrode fingers are interleaved with each other,
wherein one of a pitch or respective widths of at least a portion of the interleaved electrode fingers of the first and second plurality of electrode fingers is chirped to spread out a spur impact of a frequency response in a primary mode of the acoustic resonator, and
wherein the other of the pitch and the widths of the portion of the interleaved electrode fingers is chirped to at least partially cancel a change of the frequency response in the primary mode.

2. The acoustic resonator according to claim 1, wherein the other of the pitch and the widths of the portion of the interleaved electrode fingers is chirped to cancel at least 50% of the change of the frequency response.

3. The acoustic resonator according to claim 1,
wherein the respective widths of the portion of the electrode fingers of the first and second plurality of electrode fingers increases in a direction from the respective first ends of the first and second busbars to the respective second end of the first and second busbars, and
wherein the pitch of the portion of the electrode fingers decreases in the direction from the respective first ends of the first and second busbar to the respective second ends of the first and second busbars.

4. The acoustic resonator according to claim 1, wherein:
the portion of the electrode fingers comprises a plurality of sections of interleaved fingers with increasing widths for each section of the plurality of sections, and
the respective widths of interleaved fingers in each section is constant

5. The acoustic resonator according to claim 4, wherein the respective widths of the electrode fingers of the first and second pluralities of electrode fingers are measured relative to the first direction.

6. The acoustic resonator according to claim 1, wherein the substrate includes a base and an intermediate layer, and a portion of the piezoelectric layer forms a diaphragm that spans a cavity that extends at least partially in the intermediate layer, and the IDT is disposed on a surface of the piezoelectric layer that faces the cavity.

7. The acoustic resonator according to claim 6, wherein the piezoelectric layer and the IDT are configured such that radio frequency signals applied to the IDT excites a primary shear acoustic mode in the diaphragm.

8. The acoustic resonator according to claim 1, wherein the first direction is substantially perpendicular to the second direction.

9. The acoustic resonator according to claim 1, further comprising a Bragg mirror disposed between the piezoelectric layer and the substrate.

10. A filter device comprising:
a substrate;
at least one piezoelectric layer supported by the substrate; and
a plurality of interdigital transducers (IDTs) at a surface of the at least one piezoelectric layer, each IDT including:
a first busbar and a second busbar that each extend in a first direction from a first end to a second end thereof,
a first plurality of electrode fingers extending from the first busbar in a second direction towards the second busbar, with the second direction intersecting the first direction, and
a second plurality of electrode fingers extending from the second busbar in the second direction towards to the first busbar, such that the first and second plurality of electrode fingers are interleaved with each other,
wherein a first IDT of the plurality of IDTs comprises a first ratio of mark chirp to pitch chirp of the electrode fingers of the first and second pluralities of the electrode fingers of the first IDT, and
wherein a second IDT of the plurality of IDTs comprises a second ratio of mark chirp to pitch chirp of the electrode fingers of the first and second pluralities of the electrode fingers of the second IDT, with the second ratio being different than the first ratio.

11. The filter device according to claim 10,
wherein, for the first IDT, respective widths of the electrode fingers of the first plurality of electrode fingers increases at a first rate in the direction from the first end of the first busbar to the second end of the first busbar, and
wherein, for the second IDT, respective widths of the electrode fingers of the first plurality of electrode fingers increases at a second rate in the direction from the first end of the first busbar to the second end of the first busbar, the second rate being different than the first rate.

12. The filter device according to claim 11,
wherein a pitch of the interleaved fingers of the first IDT decreases in the direction from the first end of the first busbar of the first IDT to the second end of the first busbar of the first IDT, and
wherein a pitch of the interleaved fingers of the second IDT decreases in the direction from the first end of the first busbar of the second IDT to the second end of the first busbar of the second IDT.

13. The filter device according to claim 11, wherein the respective widths of the electrode fingers of the first and second pluralities of electrode fingers of each of the plurality of IDTs are measured relative to the first direction.

14. The filter device according to claim 10, wherein the first and second busbars of each of the plurality of IDTs extend in the first direction and are parallel to each other and the second direction is substantially perpendicular to the first direction.

15. The filter device according to claim 10, wherein the substrate includes a base and an intermediate layer and respective portions of the at least one piezoelectric layer form a plurality of diaphragms that span a plurality of cavities that extend at least partially in the intermediate layer.

16. The filter device according to claim 15, wherein the plurality of IDTs is disposed on a surface of the at least one piezoelectric layer that faces the plurality of cavities.

17. The filter device according to claim 16, wherein the at least one piezoelectric layer and the plurality of IDTs are each configured such that radio frequency signals applied to each IDT excites a primary shear acoustic mode in the respective diaphragm.

18. The filter device according to claim 10, further comprising a Bragg mirror disposed between the at least one piezoelectric layer and the substrate.

19. The filter device according to claim 11, wherein one of the mark chirp and the pitch chirp of the first IDT spreads out a spur impact of a frequency response in a primary mode of a first acoustic resonator that includes the first IDT, and the other of the mark chirp and the pitch chirp of the first IDT at least partially cancel a change of the frequency response in the primary mode of the first acoustic resonator.

20. The filter device according to claim 19, wherein one of the mark chirp and the pitch chirp of the second IDT spreads out a spur impact of a frequency response in a primary mode of a second acoustic resonator that includes the first IDT, and the other of the mark chirp and the pitch chirp of the second IDT at least partially cancel a change of the frequency response in the primary mode of the second acoustic resonator.
